(19) United States
(12) Patent Application Publication
(10) Pub. No.: US 2026/0218813 A1
(43) Pub. Date: Jul. 30, 2026

(54) SMOOTH PNEUMATIC VACUUM VALVE

(71) Applicant: VAT Holding AG, Haag (CH)

(72) Inventors: Karim ABDELAZIZ, Zürich (CH); Frantisek BALON, Sevelen (CH)

(21) Appl. No.: 19/461,036

(22) Filed: Jan. 27, 2026

(30) Foreign Application Priority Data
Jan. 29, 2025 (DE) 102025000336.6

(51) Int. Cl. F16K 51/02; F16K 3/18; F16K 31/12; F16K 37/00

(52) U.S. Cl. CPC F16K 51/02; F16K 3/18; F16K 31/12; F16K 37/0041; F16K 37/0066

(57) ABSTRACT

A vacuum transfer valve with an opening having a valve seat, a closure plate for closing the opening, a drive unit coupled to the closure plate by a valve rod configured to move the closure plate from an open to a closing position in which it is pressed against the valve seat and closes the opening, and back again. The drive unit has a first pneumatic actuator coupled to the valve rod to provide moveability of the closure plate in a first direction, a second pneumatic actuator coupled to the valve rod to provide moveability of the closure plate in a second direction, first and second pressure sensors configured to measure first and second actuation pressures in the first and second pneumatic actuators, and first and second fluid flow controllers configured to provide a defined flow of actuation fluid to or from the respective first and second pneumatic actuators.

### CROSS-REFERENCE TO RELATED APPLICATIONS

This application claims priority from German Patent Application No. 10 2025 000 336.6, filed Jan. 29, 2025, which is incorporated herein by reference as if fully set forth.

### DESCRIPTION

### Technical Field

The invention relates to a pneumatically driven vacuum valve providing a smooth and homogeneous movement of the valve closure.

### Background

Vacuum applications are typically performed in vacuum chamber systems. These applications are performed e.g. in the area of IC, semiconductor or substrate fabrication which must take place in a protected atmosphere as far as possible without the presence of contaminating particles.

The vacuum chamber systems comprise in particular at least one evacuatable vacuum chamber which is provided for receiving semiconductor elements or substrates to be processed or produced and which has at least one vacuum chamber opening, through which the semiconductor elements or other substrates can be guided into and out of the vacuum chamber. For example, in a production plant for semiconductor wafers or liquid crystal substrates, the highly sensitive semiconductor or liquid crystal elements pass sequentially through several process vacuum chambers in which the parts located within the process vacuum chambers are each processed by means of a processing device.

The process chambers typically have at least one transfer valve whose cross-section is adapted to the substrate and the robot and through which the substrate can be introduced into the vacuum chamber and, if necessary, removed after the intended processing. Alternatively, a second transfer valve may be provided through which the processed substrate is removed from the hermetic closable chamber.

Moreover, the processing system may comprise one or more peripheral units which are used especially for controlling or regulating the flow of fluid into and/or out of the vacuum chamber. The peripheral units may be provided by a regulation valve which is located between the vacuum chamber and a vacuum provider or another vacuum chamber or by a gas inlet valve, e.g. a mass-flow controller, which is arranged upstream to provide a particular type and amount of a fluid in the vacuum chamber.

A substrate to be processed, e.g. a wafer, is guided, for example, by a suitably designed and controlled robot arm, which can be guided through the opening in the process chamber provided by the transfer valve. The process chamber is then loaded by holding the substrate with the robot arm, introducing the substrate into the process chamber and depositing the substrate in the chamber in a defined manner. The process chamber is emptied accordingly.

Since transfer valves (vacuum slide gate valves) are used, inter alia, in the production of highly sensitive semiconductor elements, the particle generation, which is caused in particular by the actuation of a valve, and the number of free particles in the vacuum region of the valve chamber have to be kept as low as possible. The particle generation is primarily a result of friction, for example by metal-metal contact and by abrasion.

The sealing can be produced for example either via a seal arranged on the closure side of the closure plate (valve closure), said seal being pressed onto the valve seat running around the opening, or via a ring seal on the valve seat, against which the closure side of the closure disk is pressed. Different sealing devices are known from the prior art, for example from U.S. Pat. No. 6,629,682 B2 (Duelli). A suitable material for ring seals is the resilient sealing material known under the trade name Viton®, for example.

Since the seals used are subject to an above-average high level of wear or are destroyed when pressed with an excessively high level of force, the valves are designed in such a way that the differential pressure forces cannot act on the seals or can only act thereon to a limited extent. The seal should be pressed as uniformly as possible over its course, which requires a uniform contact pressure of the valve disk against the valve seat in the entire contact region. In particular, transverse stresses on the seal are to be kept as low as possible. In the case of transverse stresses (transverse to a normal direction of the seal) there is the risk (e.g. in the case of O-ring seals) that they will be torn from their mounting, in particular the groove in which they are fixed, or that the sealing material is damaged, and particles are created.

Different embodiments of vacuum valves, in particular the drive technologies thereof, are known from the prior art and aim to increase the service life of the used seals and also aim to provide improved process reliability.

This is typically achieved by particular motion profiles of the valve closure of respective transfer valves (slide gate valve). In a first step, the valve closure, in particular a closure plate or valve disk, as is known for example from U.S. Pat. No. 6,416,037 (Geiser) or U.S. Pat. No. 6,056,266 (Blecha), in particular of the L-type, is slid linearly over an opening substantially parallel to the valve seat, without any contact during this process between the valve closure and the valve seat. In a second step, the valve closure is pressed via the closure side thereof against the valve seat, such that the opening is closed in a gas-tight manner.

The described two-stage movement provides pressing of the seal practically exclusively perpendicularly without there being a transverse stressing of the seal.

The closing movement of such a slide gate valve occurring in two steps can be achieved by means of different mechanisms. The closure plate, mounted for example on two connecting rods, is connected via the connecting rods to a drive mechanism, which, due to a substantially linear movement along the connecting rod axis, enables a substantially parallel sliding of the closure disk over the opening to be closed. By means of the same drive mechanism, it is possible, by pivoting the connecting rods, to pivot the closure disk, which is then located opposite the opening at a distance therefrom and substantially parallel to the valve seat, in the direction of the valve seat and to press the closure disk substantially perpendicularly against the valve seat. Instead of two connecting rods, it is also possible for only one connecting rod to be used. The use of more than two connecting rods is likewise possible.

Drive mechanisms which enable both a substantially linear sliding of the closure disk over the opening and a substantially perpendicular pressing of the closure disk onto the valve seat running around the opening are known for example from U.S. Pat. No. 6,431,518 B1, U.S. Pat. No. 5,415,376 A, U.S. Pat. No. 5,641,149 A, U.S. Pat. No. 6,045,117 A, U.S. Pat. No. 5,934,646 A, U.S. Pat. No. 5,755,255 A, U.S. Pat. No. 6,082,706, U.S. Pat. No. 6,095,180 and U.S. Pat. No. 6,629,682 B2.

U.S. Pat. No. 5,769,952 discloses an alternative approach. The valve comprises a mechanism which provides changing of the movement direction of the valve closure by only moving the valve rod in one direction. Hence, an advantage of a slide gate valve of this type is the drive of relatively simple design, since the connecting rod only has to be slid linearly. US 2008/0083897 A1 also discloses a mechanism to provide sequential longitudinal movement of the valve closure in two directions.

By providing movement of the valve closure first in a direction of the valve rod and second in a direction basically perpendicular to the first direction, closing and opening of the valve opening can be provided by approaching and moving away the valve closure in a direction parallel to the surface normal of the valve seat. This results in preventing particle generation.

However, as a drawback, moving the valve closure sequentially in two directions as mentioned leads to comparatively long actuation periods to open or close the valve. Further, a proposed mechanism to convert the moving directions by use of a single driving unit is comparatively complex and, in case of maintenance or damage, highly skilled persons are required to enable further operation of the valve.

A further disadvantage of the transfer valves mentioned above is that an implemented motion profile and, in particular, a level of a pressing force between the valve disk and the valve seat is always the same. This applies for closing the valve for maintenance issues but also in the course of a regular processing cycle, for which such pressing force typically could be lower compared to maintenance. As a result, the sealing material is stressed more than - from a process point of view - would be required. Hence, the lifetime of the sealing material is reduced accordingly.

### SUMMARY

It is therefore the object of the present invention to provide an improved pneumatic vacuum valve for vacuum applications which reduces or avoids the above drawbacks.

In particular, it is an object of the invention to provide an improved pneumatic vacuum valve with an improved pneumatic actuating system which enables reliable and fast movement of the valve closure.

Further, it is an object of the present invention to provide an improved vacuum valve which provides flexibility in moving the valve closure and pressing the valve closure onto the valve seat.

These objects are solved by implementing one or more of the features disclosed herein. Features which further develop the invention in an alternative or advantageous way can be found below and in the claims.

The approach according to the invention proposes to provide at least two individually controllable pneumatic actuators to move a valve close of a vacuum transfer valve in at least two (orthogonal) directions in a simultaneous manner to provide a smooth an homogenous motion of the valve closure. The approach also allows to adjust the motions profile of the valve closure as a function of a desired application.

Controlling of the pneumatic actuators is realized by having a fluid flow controllers connected to the actuators. The fluid flow controllers provide to pressurize the actuators in defined manner by applying a defined amount of actuation fluid per time.

A fluid flow controller can be a control valve configured to control and provide defined pressure or pressure changes in the actuator, in particular in the pneumatic cylinder of the actuator or in at least one chamber of the pneumatic cylinder. Alternatively or additionally, the control valve can be configured to control and provide defined fluid flow or flow rates or changes thereof in the pneumatic actuator.

The fluid flow controller can be a proportional control valve capable of providing a defined fluid flow as a function of a respectively applied controlling signal.

Such fluid flow controller can provide a defined fluid flow into a first and/or second pneumatic actuator or a defined fluid pressure in the respective pneumatic actuator as a function of an applied controlling signal, wherein the controlling signal can provide a controlling voltage or controlling current. Further, an adjusting of the first controlling signal can comprise adjusting the controlling voltage or the controlling current to provide movement of a moving member of an actuator according to a moving information.

Feedback concerning the pressure in one of the actuators can be provided by means of a respective sensor.

The invention relates to a vacuum transfer valve with a valve wall, which has an opening and a valve seat running around the opening, and with a closure plate (valve closure) with a closure side for closing the opening in a gas-tight manner.

The vacuum transfer valve also comprises a drive unit which is coupled to the closure plate by means of a valve rod, i.e. a kind of valve guide being configured to hold and move the closure plate, and which is configured in such a way that the closure plate is moveable from an open position, in which the closure plate releases the opening (no contact between the closure plate and the valve seat), into a closing position, in which the closure side of the closure plate is pressed against the valve seat and closes the opening in gas-tight manner, and back again.

The drive unit comprises a first pneumatic actuator which is coupled to the valve rod and which is configured to provide moveability of the closure plate in a first direction. Further, the drive unit comprises a second pneumatic actuator which is coupled to the valve rod and which is configured to provide moveability of the closure plate in a second direction.

The first direction can be a linear or longitudinal direction or can alternatively be a rotational direction, e.g. a movement of the closure plate around a respective rotation axis. The second direction can also be a linear or longitudinal direction or can alternatively be a rotational direction, e.g. a movement of the closure plate around a respective rotation axis.

At least one of the pneumatic actuators can comprise a cylinder separated into two chambers by a moving member. The moving member may preferably be a piston. A stem can be is connected to the moving member and can extend outside the inner volume of the cylinder. The stem can provide the valve rod and can be configured to provide actuation of the connected valve closure to be moved.

The pneumatic actuator can further comprise a first fluid passage which passage enables fluid flow into and out of the first or second chamber of the actuator.

Further, at least one pneumatic actuator can comprise a restoring element, in particular a spring. The restoring element can be connected to the moving member and can apply a restoring force to the moving member.

The drive unit comprises a first pressure sensor arranged and configured to measure a first actuation pressure in the first pneumatic actuator and a second pressure sensor arranged and configured to measure a second actuation pressure in the second pneumatic actuator.

The pressure sensors are preferably arranged to measure the pressure in at least one chamber of the actuator.

At least one of the pressure sensors can provide pressure feedback concerning a pressure affecting the moving member.

In an alternative embodiment, at least one of the pressure sensors can be a flow meter to measure fluid flow out of the respectively connected actuator and/or into the respectively connected actuator. In an alternative embodiment, at least one of the pressure sensors may be a flow rate sensor.

The drive unit comprises a first fluid flow controller arranged and configured to provide a defined flow of actuation fluid to or from the first pneumatic actuator, and a second fluid flow controller arranged and configured to provide a defined flow of actuation fluid to or from the second pneumatic actuator.

The configuration of a vacuum transfer valve of above enables to control the motion of the closure plate (valve closure) in one single homogenous curse of motion without having to apply more than one separated motion step or sequence. This is because the closure plate can simultaneously be moved in two directions to reach the end positions of each direction basically at the same time. Further, by being enabled to control the pressures in the actuators, a pressing force for pressing the closure plate on the valve seat can be adjusted according to the requires application criteria which results to less stress and wear of the sealing material. Hence, the sealing provides longer lifetime due to less wear.

In one embodiment, the second pneumatic actuator can be coupled to the valve rod and to the closure plate. By such arrangement, individual moving of the closure plate in the second direction can be provided.

In one embodiment, the second pneumatic actuator can be coupled to valve rod to apply the motion in the second direction to the valve rod and, by that, providing a respective movement of the closure plate.

In one embodiment, the first and he second pneumatic actuator are built as an integral actuator unit to provide the motions in both directions.

In one embodiment, the first fluid flow controller and the second fluid flow controller can be sub-units of an overall fluid flow controller, wherein the general fluid flow controller provides pressurization of the first and the second pneumatic actuator.

In one embodiment, the valve rod can carry the closure plate.

According to an embodiment, the second pneumatic actuator can be coupled to the valve rod and to the closure plate and can provide movability of the closure plate relative to the valve rod. With such arrangement a direct actuation of the closure plate in a direction parallel to an opening axis of the valve opening can be provided which allows approaching and touching the valve seat in normal direction.

In an embodiment, the vacuum transfer valve can comprise a controller configured to provide movement of the closure plate according to a motion profile by controlling the first fluid flow controller and the second fluid flow controller. The controller can be embodied to generate respective controlling signal which provide respective actuations of the fluid flow controllers upon their application.

The motion profile can comprise an information about (nominal or target) positions of the closure plate in one or each direction over time, e.g. for one processing cycle. The motion profile may directly be related or comprise a respective pressure profile to be applied to the respective actuator to provide the desired motion.

At least an actuation speed, an actuation acceleration and/or a sealing force (force of pressing the closure plate on the valve seat) for the closure plate can be defined by such motion profile.

In particular, the controller can be configured to control the first fluid flow controller and the second fluid flow controller as a function of pressure information provided by the first pressure sensor and the second pressure sensor.

By measuring the pressures in the pneumatic actuators, i.e. in respectively pressurized chambers of the actuators, a direct feedback of fluid flow can be provided to control precise pressurization of the actuators according to a used motion profile.

In one embodiment, controlling of the first fluid flow controller and of the second fluid flow controller can be provided so that the motion of the closure plate comprises moving in the first direction and in the second direction simultaneously. A respective motion profile may accordingly comprise pressuring instructions for both fluid flow controller or moving instructions for both actuators.

In one embodiment, a first pressure profile can be provided to control the first fluid flow controller and a second pressure profile can be provided to control the second fluid flow controller.

According to an embodiment, the controller can be configured to provide a set of motion profiles each of which provides a superimposition of a movement of the closure plate in the first direction and a movement of the closure plate in the second direction, wherein at least two of the set of motion profiles are individually selectable to be followed by the closure plate.

By that, a motion profile matching the required application parameters can be selected, automatically or manually by an operator, to provide a respectively optimized motion behavior of the valve closure.

In one embodiment, the controller can comprise a motion profile planner, which—on execution—provides to generate or to adjust the motion profile by adapting the controlling of at least one of the first fluid flow controller and the second fluid flow controller. Such functionality provides to individually create proper motion profiles for particular applications.

In particular, the motion profile planner can comprise non-adaptable basic conditions to provide valve integrity when driving the valve with a generated or adjusted motion profile. The basic conditions can comprise at least one of
a motion offset concerning an amount of movement of the closure plate in the first direction relative to the second direction,
a speed limitation of moving the closure plate,
a limitation of the rate of changing a pressure of the actuation fluid, in particular a limitation of acceleration of the closure plate, and
a limitation concerning pressing the closure plate against the valve seat.

For instance, the motion offset can be defined to partly provide simultaneous movement in the first and second direction but to also have separated movement, in particular to prevent the closure plate to touch the valve seat and still being moved in the first direction, i.e. orthogonal to the opening axis. Such orthogonal movement could result in damaging the sealing material of the closure plate.

Further basic conditions can be defined to prevent damaging the transfer valve undesired movement.

In one embodiment, a digital model, in particular a digital twin, of the vacuum transfer valve can be provided, wherein the digital model provides description or determination of valve states as a function of the pressure information. By such model the structure and function of the valve can be derived at any instance in time by processing the pressure information.

The model can be trained to provide (near-)realistic behavior of the vacuum transfer valve, which means particular pressure measurement can be performed and assigned to respectively determined valve states. As for instance, a plurality of positions of the closure plate can be determined (e.g. by measurement) and corresponding pressure values can be derived and assigned to the positions.

The controller can further be configured to derive a first controlling signal to control the first fluid flow controller and a second controlling signal to control the second fluid flow controller based on the digital model and the pressure information.

In particular, the controller can be configured to derive a position of the closure plate as a function of the pressure information and based on the digital model.

Hence, the digital model can enable to derive position information by means of measured pressure values in real time. As a consequence, a kind of motion tracking can be provided to monitor an actual valve state (state or position of the closure plate) and to compare it with a desired target state.

In one embodiment, the vacuum transfer valve can comprise an environmental condition sensor, in particular a temperature sensor or a humidity sensor, to measure an environmental parameter, and the controller can be configured to process the environmental parameter in the course of providing the description or the determination of valve states, in particular wherein the digital model or model parameters are adapted. This additional information provides to more precisely model the transfer valve and to derive valve positions with corresponding high precision.

In one embodiment, the controller can be configured to monitor a progression of the valve state during motion of the closure plate based on the digital model and the pressure information (e.g. real-time tracking of the closure plate), compare the monitored progression of the valve state with (known and/or stored) reference valve states which are related to the (nominal or target) motion profile of the closure plate, and derive a valve operating information based on the comparing.

This approach provides a monitoring of operating the valve and to generate and provide a respective information (alert) to an operator in order to continuously be aware of any malfunctions or the like.

In one embodiment, the controller can be configured to determine a long-term trend based on the monitoring of a progression of the valve state for a plurality of controlling cycles, derive a valve state information based on the long-term trend, compare the valve state information with a pre-defined threshold, and generating a maintenance information based on the comparing.

Such derived information about the long-term trend, e.g. a long-term drift in controlling the vacuum valve, can provide respective information about possible wear or leakage (e.g. concerning the actuation fluid supply) and, based thereon, maintenance of the valve can be planned or initiated.

### BRIEF DESCRIPTION OF THE DRAWINGS

The valve according to the invention is described in detail hereinafter merely as an example with reference to specific exemplary embodiments shown schematically in the drawings, wherein further advantages of the invention are also discussed. In detail in the figures:

FIGS. 1A-1C show an embodiment of a transfer valve known from prior art.

FIG. 2 shows a motion profile of the vacuum valve known from prior art.

FIGS. 3A-3C show an embodiment of a vacuum transfer valve according to the invention.

FIG. 4 shows a motion profile of a vacuum transfer valve according to the invention.

FIGS. 5A-5B show a pressure profile and motion profile of a vacuum transfer valve according to the invention.

### DETAILED DESCRIPTION OF THE DRAWINGS

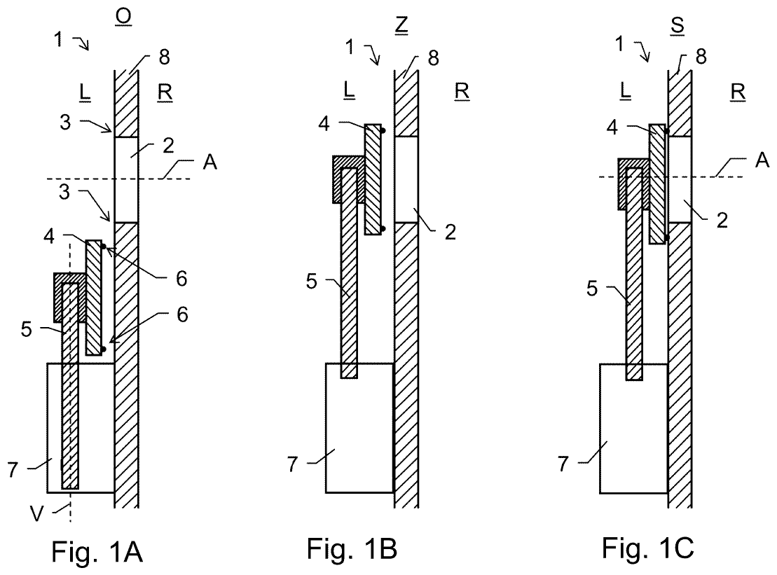

FIGS. 1A-1C show an embodiment of a vacuum transfer valve 1 according to prior art, shown in different closing positions.

The vacuum valve 1 has a rectangular, plate-shaped valve closure 4 (closure plate, valve disk), which has a sealing surface 6 for the gas-tight closure of an opening 2. The opening 2 has a cross-section corresponding to the valve closure 4 and is formed in a wall 8. The wall 8 may, for example, be the wall of a vacuum process chamber. The opening 2 is surrounded by a valve seat, which in turn also provides a sealing surface 3 corresponding to the sealing surface 6 of the valve closure 4. The sealing surface 6 of the valve closure 4 surrounds the valve closure 4 and comprises a sealing material (seal). In a closed position S (FIG. 1C), the seal is compressed between the sealing surfaces 6 and 3.

The opening 2 connects a first gas region L, which is located to the left of the wall 8, to a second gas region R to the right of the wall 8. The wall 8 is formed, for example, by a chamber wall of a vacuum chamber. The vacuum valve 1 is then formed by an interaction of the chamber wall 8 with the valve closure 4.

It will be understood that the valve seat together with the first sealing surface 3 may alternatively be formed as a valve component structurally fixed to the valve 1 and may for example be arranged, for example screwed, to a chamber opening. At least both these embodiments are covered by the present invention.

The valve closure 4 may, as shown here, be arranged on an adjustment arm 5 (valve rod), which is here for example rod-shaped, and extends along a geometrical adjustment axis V. The adjustment arm 5 is mechanically coupled to a pneumatic drive unit 7, by means of which the closure member 4 can be adjusted in the first gas region L to the left of the wall 8 by adjusting the adjustment arm 5 by means of the drive unit 7 between an open position O (FIG. 1A) via an intermediate position Z (FIG. 1B) into a closed position S (FIG. 1C).

In the open position O, the valve closure 4 is outside a projection area of the opening 2, fully exposing it.

By linearly moving the valve closure 4 in an axial direction in a plane parallel to or coaxial with the adjustment axis V and parallel to the wall 8, the valve closure 4 can be moved from the open position O to the intermediate position Z by means of the drive unit 7.

In this intermediate position Z (FIG. 1B), the sealing surface 6 of the valve closure 4 is at a distance opposite the sealing surface 3 of the valve seat surrounding the opening 2.

By adjusting in the direction of the opening axis A defined by the opening 2 (here: transverse to the adjustment axis V), i.e. e.g. perpendicular to the wall 8 and the valve seat, the valve closure 4 can be adjusted from the intermediate position Z to the closed position S (FIG. 1C).

In the closed position S, the valve disk 4 closes the opening 2 in a gas-tight manner and separates the first gas region L from the second gas region R in a gas-tight manner.

The vacuum valve is opened and closed by means of the drive unit 7, in this case by an L-shaped movement in two directions V and A of the valve closure 4, which are perpendicular to each other, for example. The valve shown is therefore also called an L-type valve.

A transfer valve 1 as shown is typically provided for sealing a process volume (vacuum chamber) and for loading and unloading the volume. Frequent changes between the open position O and the closed position S are the rule in such an application. This can lead to increased wear of the sealing surfaces 6 and 3, the interposed seal and the mechanically moved components.

Such transfer valve according to prior art provides closing and opening the valve by two steps, i.e. moving the valve closure 4 along a first axis and, subsequently, moving the valve closure 4 along a second axis, which is perpendicular to the first axis. Due to the required sequential movement, opening and closing periods of the valve are comparatively time consuming.

The structural design of the transfer valve 1 provides one general motion profile, i.e. acceleration, speed and sealing force are fixed. As a consequence, the mentioned parameters are defined so that a closing state of the valve fulfils sealing requirements of every application purpose. This results in a high-level sealing force (the force which the valve closure is pressed onto the valve seat) which is also sufficient when the processing chamber is vented, e.g. for chamber cleaning processes. However, the sealing force for closing the valve in the course of a typical processing step under vacuum conditions could be significantly lower to still meet respective processing requirements. In consequence the sealing material is loaded more heavily than necessary and lifetime of the seal is shortened respectively.

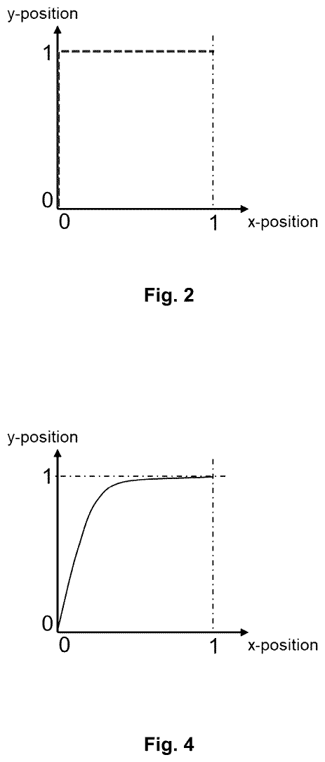

FIG. 2 shows a motion profile of the vacuum valve according to FIGS. 1A-1C.

As described above, the drive mechanism of the valve 1 is a two-axis (vertical-horizontal) motion mechanism, where the actuation of the valve closure 4 is to be performed sequentially, in particular including a defined delay for each axis (due to the absence of position information) to ensure proper valve opening and closing this in return causes long actuation time.

This sequential actuation is shown for a closing process, i.e. changing the valve state from the open position O to the closed position S. First the valve closure 4 is moved along the adjustment axis V which corresponds to changing the y-position of the closure 4. After having reached the extended state of the valve rod 5, i.e. when the valve closure is brought into the intermediate position Z, the valve closure 4 is moved along the opening axis A perpendicular to the adjustment axis V until the valve is closed. This second motion part along the opening axis A corresponds to a change of the x-position as shown.

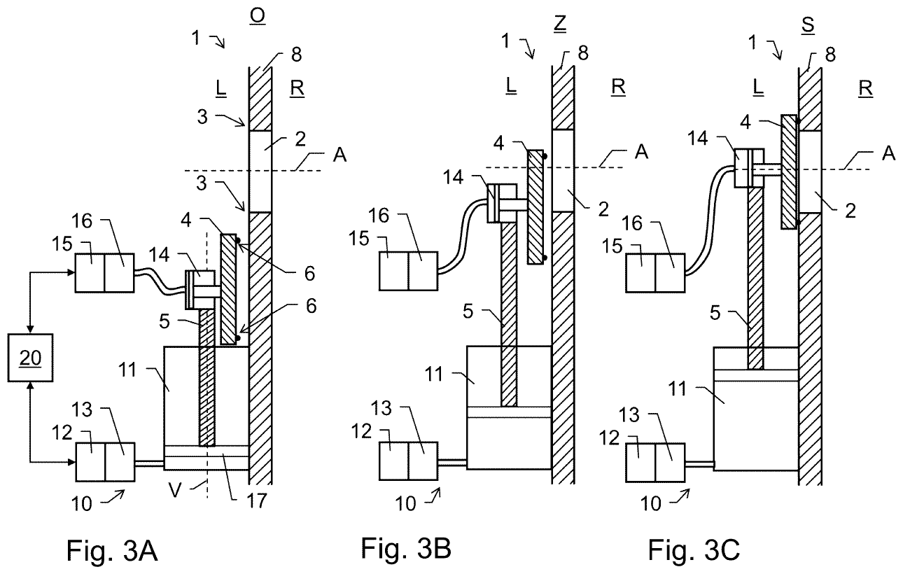

FIGS. 3A-3C show an embodiment of a vacuum transfer valve 1 according to the invention in different closing positions.

This embodiment is different from the embodiment of FIGS. 1A-1C by having a different drive unit 10.

The drive unit 10 comprises a first pneumatic actuator 11 which is coupled to the valve rod 5 which here is embodied as a valve rod. The drive unit 10 is configured to provide moveability of the closure plate 4 in a first (longitudinal) direction. The first direction is a direction corresponding an extension of the adjustment axis V, i.e. a movement of the valve rod 5 along the adjustment axis V.

The first pneumatic actuator 11 is connected to a first fluid flow controller 12 which is arranged and configured to provide a defined flow of actuation fluid to or from the first pneumatic actuator 11.

Further, a first pressure sensor 13 is arranged and configured to measure a first actuation pressure in the first pneumatic actuator 11, i.e. a pressure which is applied to the first pneumatic actuator 11.

The first pneumatic actuator 11 comprises a restoring element (not shown), e.g. a spring, which provides a restoration forces acting against an actuation forces which is applied to the valve rod 5 by pressurization of the first pneumatic actuator 11.

In an alternative embodiment (not shown), the first pneumatic actuator 11 can comprise a further fluid flow controller which is connected to the actuator 11 to provide pressurization of an opposite side of a moving member 17 inside of the actuator 11. By that, countermovement of the valve closure in opposite direction can be provided and controlled, as well.

The drive unit 10 also comprises a second pneumatic actuator 12 which is coupled to the valve rod 5 and which is configured to provide moveability of the closure plate 4 in a second (longitudinal) direction. The second direction is a direction orthogonal to the first direction. Here, the second direction corresponds an extension of the opening axis A in the closing state S of the valve or is parallel to the opening axis A.

The second pneumatic actuator 14 is connected to a second fluid flow controller 15 which is arranged and configured to provide a defined flow of actuation fluid to or from the second pneumatic actuator 14.

Further, a second pressure sensor 16 is arranged and configured to measure a first actuation pressure in the second pneumatic actuator 14, i.e. a pressure which is applied to the second pneumatic actuator 14.

The second pneumatic actuator 14 may comprise a spring or an additional fluid flow controller, as described above for the first actuator, to provide (and control) countermovement of the valve plate, i.e. in a direction opposite to the second direction.

The vacuum transfer valve 1 also comprises a controller 20. The controller 20 is connected with the first fluid flow controller 12 and the second fluid flow controller 15 to control fluid flow through the flow controllers and is connected with the first pressure sensor 13 and the second pressure sensor 16 to receive pressure information related to the pressures in the actuators 11 and 14.

The controller 20 is configured to provide movement of the closure plate 4 according to a motion profile by controlling the first fluid flow controller 12 and the second fluid flow controller 15 as a function of pressure information provided by the first pressure sensor 13 and the second pressure sensor 16.

The controller 20 is configured to provide controlling of the first fluid flow controller 12 and of the second fluid flow controller so that the motion profile comprises moving of the closure plate 4 in the first direction and in the second direction simultaneously. In other words, the first and the second pneumatic actuator are pressurized at least in part at the same time.

As a result, changing the valve state or the state of the valve closure 4 from an open state O into a closed state (or the other way around) can be realized with significantly less time consumption. This is because closing the valve has not to be performed in two separate motion steps but one smooth and homogeneous motion of the closure 4 is provided. Such smooth movement further provides reducing particle generation and vibrations due to the soft opening and closing.

The controller 20 is further configured to process the pressure information to detect distinct positions (e.g. closed position) of the valve closure 4. By that, a real-time tracking of the valve closure 4 can be provided. Based thereon the pressure profile can be adapted to minimize vibration and particle generation in addition to simultaneously actuating other axes and reduce overall actuation time.

In particular, a digital model, e.g. a digital twin, of the vacuum transfer valve 1 is provided. The digital model provides description or determination of valve states as a function of the (measured) pressure information. In other words, knowing about the pressure in a pneumatic actuator enables one to derive e.g. a position of the valve closure 4. The controller 20 can respectively be configured to derive a first controlling signal to control the first fluid flow controller and a second controlling signal to control the second fluid flow controller based on the digital model and the pressure information.

In addition, motion control or position control of the pneumatic cylinders can be used purely by means of the digital twin or the models without use of any real time feedback position measurement or indicator. Hence, controlling can be provided in an open loop and sensor-less.

To adjust the digital twin to best correspond real world conditions, environmental information like temperature or humidity, friction or other environmental condition can be derived (e.g. measured or by simulation) to adjust the model parameters or movement parameters accordingly.

Based on the digital model and the pressure information, a progression of the valve state during motion of the closure plate 4 can be monitored. By that, if the travel path of the gate (valve closure) is, for example, blocked with an obstacle, a related early pressure rise can be detected and in combination with digital twin referencing the actual position enables to derive unwanted states of the transfer valve.

Further, the monitored progression of the valve state can be compared with reference valve states which are related to the motion profile of the closure plate, and a valve operating information can be derived based on such comparison.

The digital model can also be used for predictive maintenance of the valve. For that, a long-term trend of the valve states or realized motion profiles can be derived based on pressure measurement and a processing of the measured pressures with digital model. Such model-based processing can be done over a number of processing cycles or a period of time. The results of the processing can be compared with each others of with a reference value and the trend can be derived based thereon. Based on the trend, maintenance of the valve can respectively be planned.

Since the actuations of the pneumatic actuators are individually controllable the motion of the closure plate 4 can be optimized with respect to a particular application which should be provided by the valve. Such applications can for instance be a venting of the processing chamber or a typical processing step in the chamber. In case of venting the processing chamber a force for pressing the valve closure 4 on the valve seat 3 has to be greater than a respective force required for processing. This is because of the significantly higher pressure difference between the first gas region L and the second gas region R when venting the chamber.

According to the invention, the pneumatic actuators 11,14 are controllable by means of their fluid flow controllers 12,15, i.e. by adjusting an amount of fluid flowing into (or out of) the pneumatic actuators 11,14. The pressures in the actuators 11,14 are directly depending on the fluid flows. This means that the pressure in e.g. the pneumatic actuator 14 can be controlled and varied and the (pressing) force for pressing the valve closure 4 on the valve seat 3 can be adjusted as well.

The motion profile for the pneumatic actuator 14 or for the pneumatic actuator 11 or for the general motion of the valve can respectively comprise applied pressure levels over time.

Hence, the transfer valve 1 can be differently controlled according to an applied or desired application by e.g. changing the motion profile or the controlling parameters which are processed for controlling the fluid flow controllers 12,15.

The controller can accordingly be configured to provide a set of motion profiles each of which can be provided by a superimposition of a movement of the closure plate in the first direction and a movement of the closure plate in the second direction. At least two of the set of motion profiles are individually selectable to be followed by the closure plate 4. In particular, the motion profiles are related to respective controlling parameters to control the fluid flow controllers 12,15.

FIG. 4 shows a motion profile of the vacuum valve according to the invention.

As described above, the drive unit of a valve according to the invention is a simultaneous two-axis (vertical-horizontal) pneumatic motion drive, where the actuation of the valve closure 4 is to be performed with one single sequence, in particular including a superimposition of a movement in x- and y-direction. This provides for smooth motion of the valve closure 4 and respectively soft closing with shorter actuation times.

This simultaneous actuation is shown for a closing process, i.e. changing the valve state from the open position O to the closed position S. The valve closure 4 is moved along the adjustment axis V which corresponds to changing the y-position of the closure 4 and also is moved in a direction parallel or corresponding to the opening axis A, perpendicular to the adjustment axis V, at the same time. The valve closure 4 reaches its end-position in x-and y-direction basically at the same time. In one preferred embodiment, the movement along the adjustment axis V (y-position) is completed before the movement in orthogonal direction.

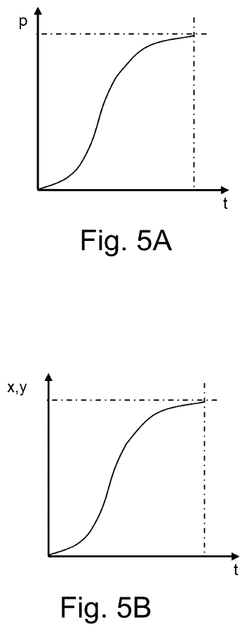

FIG. 5A shows a pressure profile of a pneumatic actuator for controlling a motion to close the valve according to the invention. As can be seen, the pressure level starts increasing with a small slope. Afterwards the pressure increases stronger for providing shorter actuation times. In a third motion phase, for approaching the valve closure to the valve seat, the pressure increase is smaller again to provide soft touching.

FIG. 5B shows a corresponding motion profile of the valve closure 4 in x-direction and in y-direction, i.e. along the adjustment axis V and orthogonal to the axis V, over time which is a result of applying the pressure profile according to FIG. 5A.

The motion performance respectively follows the pressure profile. This results in adjusted fast but smooth movement of the valve closure which also provides a soft closing of the valve.

The force of pressing the valve closure 4 on the valve seat 3 can be adjusted by e.g. generally increasing the final pressure level, in particular concerning the second pneumatic actuator 14.

It is understood that the depicted figures only schematically depict possible exemplary embodiments. The various approaches can according to the invention also be combined with one another and with prior art methods and devices for controlling of a pneumatic transfer valve.

1. A vacuum transfer valve (1), comprising:
a valve wall (8), which has an opening (2) and a valve seat (3) running around the opening (2);
a closure plate (4) with a closure side for closing the opening (2) in a gas-tight manner;
a drive unit (10) which is coupled to the closure plate (4) by a valve rod (5) and which is configured such that the closure plate (4) is moveable from an open position (O), in which the closure plate (4) releases the opening (2), into a closing position (C), in which a closure side of the closure plate (4) is pressed against the valve seat (3) and closes the opening (2) in gas-tight manner, and back again;
wherein the drive unit (10) comprises:
a first pneumatic actuator (11) which is coupled to the valve rod (5) and which is configured to provide moveability of the closure plate (4) in a first direction,
a second pneumatic actuator (14) which is coupled to the valve rod (5) and which is configured to provide moveability of the closure plate (4) in a second direction,
a first pressure sensor (13) arranged and configured to measure a first actuation pressure in the first pneumatic actuator (11),
a second pressure sensor (16) arranged and configured to measure a second actuation pressure in the second pneumatic actuator (14),
a first fluid flow controller (12) arranged and configured to provide a defined flow of actuation fluid to or from the first pneumatic actuator (11), and
a second fluid flow controller (15) arranged and configured to provide a defined flow of the actuation fluid to or from the second pneumatic actuator (14).

2. The vacuum transfer valve (1) according to claim 1, wherein the second pneumatic actuator (14) is coupled to the valve rod (5) and to the closure plate (4).

3. The vacuum transfer valve (1) according to claim 1, wherein the second pneumatic actuator (14) is coupled to the valve rod (5) and the closure plate (4) and provides movability of the closure plate (4) relative to the valve rod (5).

4. The vacuum transfer valve (1) according to claim 1, further comprising a controller (20) configured to provide movement of the closure plate (4) according to a motion profile by controlling the first fluid flow controller (12) and the second fluid flow controller (15).

5. The vacuum transfer valve (1) according to claim 4, wherein the controller (20) is configured to control the first fluid flow controller (12) and the second fluid flow controller (15) as a function of pressure information provided by the first pressure sensor (13) and the second pressure sensor (16).

6. The vacuum transfer valve (1) according to claim 5, wherein controlling of the first fluid flow controller (12) and of the second fluid flow controller (15) is provided so that the motion of the closure plate (4) comprises moving in the first direction and in the second direction simultaneously.

7. The vacuum transfer valve (1) according to claim 4, wherein a first pressure profile is provided to control the first fluid flow controller and a second pressure profile is provided to control the second fluid flow controller.

8. The vacuum transfer valve (1) according to claim 4, wherein the controller (20) is configured to provide a set of motion profiles each of the motion profiles provides a superimposition of a movement of the closure plate (4) in the first direction and a movement of the closure plate (4) in the second direction, and at least two of the set of motion profiles are individually selectable to be followed by the closure plate (4).

9. The vacuum transfer valve (1) according to claim 4, wherein the controller (20) comprises a motion profile planner, which is adapted to generate or to adjust the motion profile by adapting the controlling of at least one of the first fluid flow controller (12) and the second fluid flow controller (15).

10. The vacuum transfer valve (1) according to claim 9, wherein the motion profile planner comprises non-adaptable basic conditions to provide valve integrity when driving the vacuum transfer valve (1) with a generated or to adjusted motion profile, wherein the basic conditions comprise at least one of
a) a motion offset concerning an amount of movement of the closure plate (4) in the first direction relative to the second direction,
b) a speed limitation of moving the closure plate (4),
c) a limitation of the rate of changing a pressure of the actuation fluid,
d) a limitation of acceleration of the closure plate (4), and
e) a limitation concerning pressing the closure plate (4) against the valve seat (3).

11. The vacuum transfer valve (1) according to claim 9, further comprising
a digital model of the vacuum transfer valve, wherein the digital model provides description or determination of valve states as a function of the pressure information, and
the controller is configured to derive a first controlling signal to control the first fluid flow controller and a second controlling signal to control the second fluid flow controller based on the digital model and the pressure information.

12. The vacuum transfer valve (1) according to claim 11, wherein the controller (20) is configured to derive a position of the closure plate (4) as a function of the pressure information based on the digital model.

13. The vacuum transfer valve (1) according to claim 12, further comprising an environmental condition sensor to measure an environmental parameter, and the controller (20) is configured to process the environmental parameter during providing the description or the determination of valve states.

14. The vacuum transfer valve (1) according to claim 13, wherein the controller (20) is configured to
a) monitor a progression of the valve state during motion of the closure plate (4) based on the digital model and the pressure information,
b) compare the monitored progression of the valve state with reference valve states which are related to the motion profile of the closure plate (4), and
c) derive a valve operating information based on the comparing.

15. The vacuum transfer valve (1) according to claim 14, wherein the controller (20) is configured to
a) determine a long-term trend based on the monitoring of a progression of the valve state for a plurality of controlling cycles,
b) derive a valve state information based on the long-term trend,
c) compare the valve state information with a pre-defined threshold, and
d) generate a maintenance information based on the comparing.
